(19) United States
(12) Patent Application Publication
(10) Pub. No.: US 2015/0194630 A1
(43) Pub. Date: Jul. 9, 2015

(54) DISPLAY DEVICE AND METHOD OF MANUFACTURING THE SAME

(71) Applicant: Samsung Display Co., Ltd., Yongin-City (KR)

(72) Inventor: Akira Hirai, Yongin-City (KR)

(21) Appl. No.: 14/509,663

(22) Filed: Oct. 8, 2014

(30) Foreign Application Priority Data
Jan. 7, 2014 (KR) 10-2014-0002085

(51) Int. Cl. H01L 51/52; H01L 27/32; H01L 51/56

(52) U.S. Cl. CPC H01L 51/5253; H01L 51/56; H01L 27/3276; H01L 2227/323

(57) ABSTRACT

A display device and method of manufacturing the same are disclosed. In one aspect, the display device includes a substrate, at least one wire formed over the substrate and configured to transfer a signal for displaying an image, and an encapsulating unit formed over the wire and comprising a base layer and a barrier layer. The barrier layer is interposed between the wire and the base layer and includes a lower surface having a shape that corresponds to the shape of the wire and an upper surface opposing the lower surface. The base layer has a lower surface having a shape that corresponds to the shape of the barrier layer.

### RELATED APPLICATIONS

This application claims the benefit of Korean Patent Application No. 10-2014-0002085, filed on Jan. 7, 2014, in the Korean Intellectual Property Office, the disclosure of which is incorporated herein in its entirety by reference.

### BACKGROUND

1. Field

The described technology generally relates to a display device and a method of manufacturing the same.

2. Description of the Related Technology

Display devices have a wide variety of applications. Due to the development of slimmer and lighter displays, the applications for displays are becoming more diverse. Display devices include a display unit configured to display images and the display unit includes various conductive layers, insulating layers, organic layers, and the like. Wires electrically connect the display unit to other components.

Display devices include an encapsulating unit to cover and/or protect an area including the display unit. The encapsulating unit prevents moisture, air, and other contaminants from penetrating into the area including the display unit, and thus, contributes to the durability of the display device.

### SUMMARY OF CERTAIN INVENTIVE ASPECTS

One inventive aspect is a display device including a substrate, at least one wiring unit formed on the substrate, the at least one wiring unit transferring a signal for displaying an image, and an encapsulating unit formed on the wiring unit, the encapsulating unit including a base member and a barrier member. The barrier member is formed between the at least one wiring unit and the base member and includes an uneven upper surface that corresponds to the wiring unit and the base member has an uneven surface where at least a portion of the uneven surface facing the wiring unit corresponds to the wiring unit.

The base member may have an elasticity of about 10 MPa or less.

The base member may include thermoplastic resin, elastomer, a hot melt adhesive, or a low elastic adhesive film.

The barrier member may include an inorganic material.

The barrier member may include at least one inorganic layer and at least one organic layer that are stacked and the at least one inorganic layer may be formed at least on a surface of the barrier member facing the wiring unit.

The barrier member may contact the wiring unit.

A protruding and depressing surface that corresponds to the wiring unit may be formed on the opposite surface of the uneven surface of the barrier member.

The base member may be thicker than the barrier member.

A thickness of the barrier member may be about 0.01 μm to about 1 μm.

A display unit is formed on the substrate, the display unit displaying the image, and a driving unit that is separated from the display unit and drives the display unit is formed on the substrate. The wiring unit may electrically connect the display unit to the driving unit.

The display unit may include an organic light-emitting diode (OLED) device and the OLED may include a first electrode, a second electrode, and an intermediate layer that is formed between the first and second electrodes and at least includes an organic emission layer.

Another aspect is a method of manufacturing a display device, including preparing a substrate, forming, on the substrate, at least one wiring unit that transfers a signal for displaying an image, and forming, on the at least one wiring unit, an encapsulating unit including a base member and a barrier member. The barrier member is formed between the at least one wiring unit and the base member and includes an uneven upper surface that corresponds to the wiring unit and the base member has an uneven surface where at least a portion of the uneven surface facing the wiring unit corresponds to the wiring unit.

The forming of the encapsulating unit may include applying a pressure to at least one of the encapsulating unit and the substrate.

The pressure may be applied at a temperature that is substantially equal to or greater than a glass transition temperature of the base member.

Before applying the pressure, a silicon thin film may be formed on a surface of the barrier member of the encapsulating unit, and a surface of the substrate and a surface of the wiring unit, which are at a location corresponding to the surface of the barrier member, and then energy may be irradiated to activate the silicon thin film.

Before applying the pressure, a plasma process may be performed on a surface of the barrier member of the encapsulating unit, and from among a surface of the substrate and a surface of the wiring unit, which are formed at a location corresponding to the surface of the barrier member, at least on the surface of the wiring unit.

Before applying the pressure, a monomolecular layer may be formed on a surface of the barrier member of the encapsulating unit, and at least one of a surface of the substrate and a surface of the wiring unit, which are formed at a location corresponding to the surface of the barrier member.

The barrier material may include an inorganic material.

A protruding and depressing surface that corresponds to the wiring unit may be formed on the opposite surface of the uneven surface of the barrier member.

The base member may be thicker than the barrier member.

Another aspect is a display device including a substrate, at least one wire formed over the substrate and configured to transfer a signal for displaying an image, and an encapsulating unit formed over the wire and including a base layer and a barrier layer, wherein the barrier layer is interposed between the wire and the base layer and includes a lower surface having a shape that corresponds to the shape of the wire and an upper surface opposing the lower surface, wherein the base layer has a lower surface having a shape that corresponds to the shape of the barrier layer.

The base layer can have an elasticity of about 10 MPa or less. The base layer can be formed of thermoplastic resin, elastomer, a hot melt adhesive, or a low elastic adhesive film. The barrier layer can be formed of an inorganic material. The barrier can include at least one inorganic layer and at least one organic layer that are stacked and the at least one inorganic layer can be formed on the lower surface of the barrier layer. The barrier layer can contact the wire. The thickness of the barrier layer can be substantially uniform. The base layer can be thicker than the barrier layer. The thickness of the barrier layer can be in the range of about 0.01 μm to about 1 μm. The display device can include a display unit formed on the substrate and configured to display the image and a driver separated from the display unit and configured to drive the display unit, wherein the wire electrically connects the display unit to the driver. The display unit can further include an organic light-emitting diode (OLED) and the OLED can include a first electrode, a second electrode, and an intermediate layer interposed between the first and second electrodes and including an organic emission layer.

Another aspect is a method of manufacturing a display device including providing a substrate, forming at least one wire over the substrate, and forming an encapsulating unit over the wire, wherein the encapsulating unit includes a base layer and a barrier layer, wherein the barrier layer is interposed between the wire and the base layer and includes a lower surface having a shape that corresponds to the shape of the wire and an upper surface opposing the lower surface and wherein the base layer has a lower surface having a shape that corresponds to the shape of the barrier layer.

The forming of the encapsulating unit can include applying pressure to at least one of the encapsulating unit and the substrate. The pressure can be applied at a temperature that is substantially equal to or greater than a glass transition temperature of the base layer. The method can further include forming a silicon thin film on each of the lower surface of the barrier layer, an upper surface of the substrate, and an upper surface of the wire before the applying and irradiating energy onto the silicon thin films. The method can further include performing a plasma process on each of the lower surface of the barrier layer and an upper surface of the wire before the applying. The method can further include forming a monomolecular layer on each of the lower surface of the barrier layer and at least one of an upper surface of the substrate and an upper surface of the wire before the applying. The forming of the encapsulating unit can include applying pressure to at least one of the encapsulating unit and the substrate. The pressure can be applied at a temperature that is substantially equal to or greater than a glass transition temperature of the base layer. The method can further include forming a silicon thin film on each of the lower surface of the barrier layer, an upper surface of the substrate, and an upper surface of the wire before the applying and irradiating energy onto the silicon thin films. The method can further include performing a plasma process on each of the lower surface of the barrier layer and an upper surface of the wire before the applying. The method can further include forming a monomolecular layer on each of the lower surface of the barrier layer and at least one of an upper surface of the substrate and an upper surface of the wire before the applying. The barrier layer can be formed of an inorganic material. The base can be thicker than the barrier layer.

Another aspect is a display device including a substrate, at least one wire formed over the substrate and configured to transfer a signal for display an image, a first encapsulation layer formed over the wire and including a lower surface having a shape that corresponds to the shape of the wire and an upper surface opposing the lower surface, and a second encapsulation layer formed over the first encapsulation layer and including a lower surface having a shape that corresponds to the shape of the first encapsulation layer.

### BRIEF DESCRIPTION OF THE DRAWINGS

FIG. 1 is a schematic sectional view of a display device according to an embodiment.

FIG. 2 is a schematic plan view of a display device according to another embodiment.

FIG. 3 is a cross-sectional view taken along line III-III of the display device of FIG. 2.

FIG. 4 is an enlarged view of region X of FIG. 3;

FIG. 5 is a cross-sectional view taken along line V-V of the display device of FIG. 2.

FIGS. 6A to 6E are views sequentially illustrating a method of manufacturing a display device according to an embodiment.

### DETAILED DESCRIPTION OF CERTAIN INVENTIVE EMBODIMENTS

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the described technology. Expressions such as “at least one of,” when preceding a list of elements, modify the entire list of elements and do not modify the individual elements of the list.

It will be understood that although the terms “first”, “second”, etc. may be used herein to describe various components, these components should not be limited by these terms. These terms are only used to distinguish one component from another.

As used herein, the singular forms “a”, “an”, and “the” are intended to include the plural forms as well, unless the context clearly indicates otherwise.

It will be understood that the terms “comprises” and/or “comprising” used herein specify the presence of the stated features or components, but do not preclude the presence or addition of one or more other features or components.

It will be understood that when a layer, region, or component is referred to as being “formed on,” another layer, region, or component, it can be directly or indirectly formed on the other layer, region, or component. That is, for example, intervening layers, regions, or components may also be present.

The sizes and thicknesses of elements in the drawings may be exaggerated for the sake of clarity. In other words, since the sizes and thicknesses of components in the drawings may be exaggerated for convenience of explanation, the following embodiments are not limited thereto.

In the following examples, the x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

Certain embodiments may be implemented differently and a specifically described or illustrated process order can be performed differently from the described order. For example, two consecutively described processes may be performed substantially at the same time or performed in an order opposite to the described order. The term “substantially” as used in this disclosure means completely, almost completely, or to any significant degree.

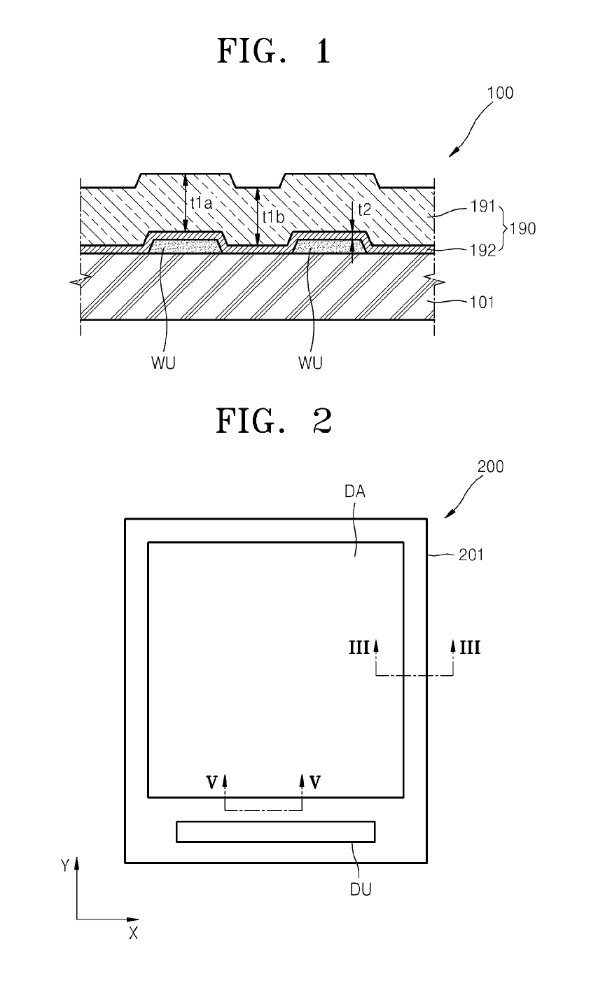

FIG. 1 is a schematic sectional view of a display device 100 according to an embodiment.

Referring to FIG. 1, the display device 100 includes a substrate 101, a wiring unit or wire WU, and an encapsulating unit 190. The encapsulating unit 190 includes a base member or base layer 191 and a barrier member or barrier layer 192.

The display device 100 displays images that can be recognized at least by a user. That is, although not illustrated in FIG. 1, the display device 100 displays images in an upper or lower direction. A display unit (not shown) displaying the image is defined by a predetermined area and the wiring unit WU is formed on the substrate 101 to transfer predetermined electric signals, e.g., scan signals, data signals, or other electric signals to the display unit (not shown).

Hereinafter, each element will be described in detail.

The substrate 101 may be formed of various materials. The substrate 101 may be formed of a glass material, for example, a glass material that transmits light. Alternatively, the substrate 101 may be formed of a flexible material, for example, a plastic material. The plastic material that forms the substrate 101 may be at least one organic material.

Alternatively, the substrate 101 may be formed as a metal thin film.

At least one wiring unit WU is formed on the substrate 101. For example, as illustrated in FIG. 1, a plurality of wiring units WU are formed on the substrate 101. Although not illustrated, in some embodiments, at least one insulating layer (not shown) is further included between the substrate 101 and the wiring unit WU. In other embodiments, at least one conductive layer (not shown) is further formed between the substrate 101 and the wiring unit WU and is electrically connected to the wiring unit WU or is insulated from the wiring unit WU.

As described above, the wiring unit WU transfers various electric signals used in displaying an image on the display device 100. Therefore, the wiring unit WU is formed by using various materials having high conductivity.

The encapsulating unit 190 is formed to cover the wiring unit WU. The encapsulating unit 190 includes the base member 191 and the barrier member 192.

Although not illustrated, in some embodiments, at least one protection layer (not shown) is formed between the encapsulating unit 190 and the wiring unit WU. The protection layer may be formed of an insulating material. For example, the protection layer may be formed of an oxide material or a nitride material.

According to some embodiments, the base member 191 is formed of a low elastic material. Therefore, the base member 191 may have protrusions and depressions that correspond to the shape of the wiring unit WU, regardless of the thickness of the wiring unit WU formed under the base member 191. In particular, the surface of the base member 191 that faces the wiring unit WU, i.e., the lower surface of the base member 191 as shown in FIG. 1, has a protruding and depressing surface that corresponds to protrusions and depressions of the upper surface of the wiring unit WU. Therefore, the encapsulating unit 190 including the base member 191 and the barrier member 192 substantially completely encompasses the wiring unit WU to prevent moisture or external air from penetrating into the wiring unit WU.

In some embodiments, the base member 191 is formed of a low elastic material that has an elasticity of about 10 MPa or less. Since the base member 191 is formed of such a low elastic material, the upper surface of the base member 191, i.e., the surface opposite to the surface facing the wiring unit WU, is not smoothly formed, but includes a protruding and depressing surface that corresponds to the shape of the wiring unit WU.

According to an embodiment, the base member 191 includes a thermoplastic resin. For example, the base member 191 includes methyl methacrylate (MMA), PC, PET, cyclo-olefin-polymer (COP), cyclo-olefin-copolymer (COC), polyimide, or a combination thereof. Respective glass transition temperatures (Tg) of the above-described materials are about 80° C. to about 100° C. or greater. During a process of forming the encapsulating unit 190 including the base member 191, the working temperature is greater than the Tg of the above-described materials.

According to another embodiment, the base member 191 includes an elastomer. For example, the base member 191 includes styrene-based synthetic rubber or silicon-based synthetic rubber. Also, the base member 191 may include a block copolymer of MMA and butyl-acrylate (BA).

According to yet another embodiment, the base member 191 is a hot melt adhesive, including a polyester-based hot melt film, a synthetic rubber-based hot melt film, a modified olefin-based hot melt film, an ethylene-vinyl-acetate (EVA)-based hot melt film, an isocyanate-based hot melt film, or a combination thereof.

According to still yet another embodiment, the base member 191 is an adhesive film having a low elasticity, including an acryl-based adhesive film, a synthetic rubber-based adhesive film, a polyester-based adhesive film, a silicon rubber-based adhesive film, a urethane-based adhesive film, or a combination thereof.

The barrier member 192 is formed on the wiring unit WU to cover the wiring unit WU. Also, the barrier member 192 contacts the base member 191. In some embodiments, the barrier member 192 includes an inorganic material, such as an oxide material or a nitride material. In other embodiments, the barrier member 192 includes at least one inorganic layer and at least one organic layer. In these embodiments, the surface of the barrier member 192 that is closest to the wiring unit WU is an inorganic layer.

The barrier member 192 has a thickness t2. The thickness t2 of the barrier member 192 is less than thicknesses t1a and t1b of the base member 191. Specifically, in some embodiments, the thickness t2 of the barrier member 192 is about 1 μm or less. Therefore, the barrier member 192 has a protruding and depressing surface that corresponds to the shape of the wiring unit WU and cracks are not formed in the barrier member 192 when the protrusions and depressions are formed. However, according to other embodiments, the thickness t2 of the barrier member 192 is greater than about 1 μm.

In some embodiments, the thickness t2 of the barrier member 192 is about 0.01 μm or greater. When the thickness t2 of the barrier member 192 is less than about 0.01 μm the encapsulating properties thereof decrease. However, according to other embodiments, the thickness t2 of the barrier member 192 is less than about 0.01 μm.

The base member 191 has predetermined thicknesses. Specifically, the portion of the base member 191 that corresponds to the wiring unit WU has the thickness t1a and the portion the base member 191 that does not correspond to the wiring unit WU has the thickness t1b. The thicknesses t1a and t1b are the same as or similar to each other. Since the base member 191 includes a low elastic material and thus has protrusions and depressions that correspond to the protrusions and depressions of the wiring unit WU, the base member 191 has a substantially uniform thickness throughout.

The base member 191 is thicker than the barrier member 192 and has a thickness of about 5 μm to about 100 μm. When the thickness is less than about 5 μm, the encapsulating properties thereof decrease, thereby decreasing the ability of the base member 191 to block moisture and external air transmission. When the thickness is greater than about 100 μm, the base member 191 may not be able to easily form protrusions and depressions that correspond to the wiring unit WU, and thus the contact strength between the encapsulating unit 190 and the wiring unit WU may decrease. However, depending on the embodiment, the base member 191 can have a thickness that is less than about 5 μm or greater than about 100 μm.

The display device 100 according to the embodiment of FIG. 1 includes the encapsulating unit 190 that covers the wiring unit WU. The encapsulating unit 190 includes the base member 191 and the barrier member 192. Regardless of the thickness and width of the wiring unit WU, the encapsulating unit 190 is formed to contact the upper surface of the wiring unit WU by forming the base member 191 by using the above-described materials, in particular, a low elastic material having an elasticity of about 10 MPa or less.

The thickness of the barrier member 192 that is formed near the wiring unit WU is formed to be less than the thickness of the base member 191, for example, about 1 μm or less. Therefore, the barrier member 192 is formed to have protrusions and depressions that correspond to the shape of the wiring unit WU so that the barrier member 192 and the wiring unit WU are not separated and contact each other.

In other embodiments, when the at least one insulating layer is interposed between the wiring unit WU and the barrier member 192, the barrier member 192 contacts the insulating layer.

Accordingly, the encapsulating properties of the display device 100 are improved, and thus the durability thereof is improved. Since the encapsulating unit 190 is flexible overall, when the substrate 101 is formed of a flexible material, it is possible to easily form a display device 100 that can be bent or folded by a user.

Referring to FIGS. 2 to 5, a display device 200 according to another embodiment includes a substrate 201, a display unit DA, a driving unit or driver DU, a wiring unit WU, and an encapsulating unit 290. The encapsulating unit 290 includes a base member 291 and a barrier member 292.

The display device 200 displays images that can be recognized at least by a user. That is, as illustrated in FIG. 2, the display device 200 includes the display unit DA that has as an area with a predetermined size on the substrate 201.

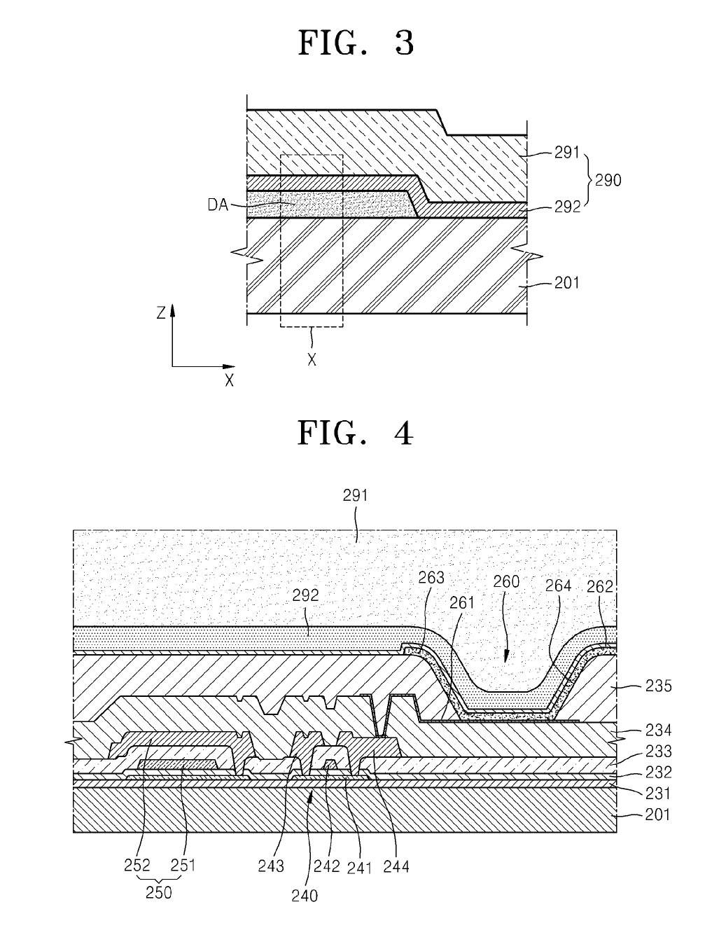

The display unit DA displays images in an upper or a lower direction with respect to the illustration of FIG. 3.

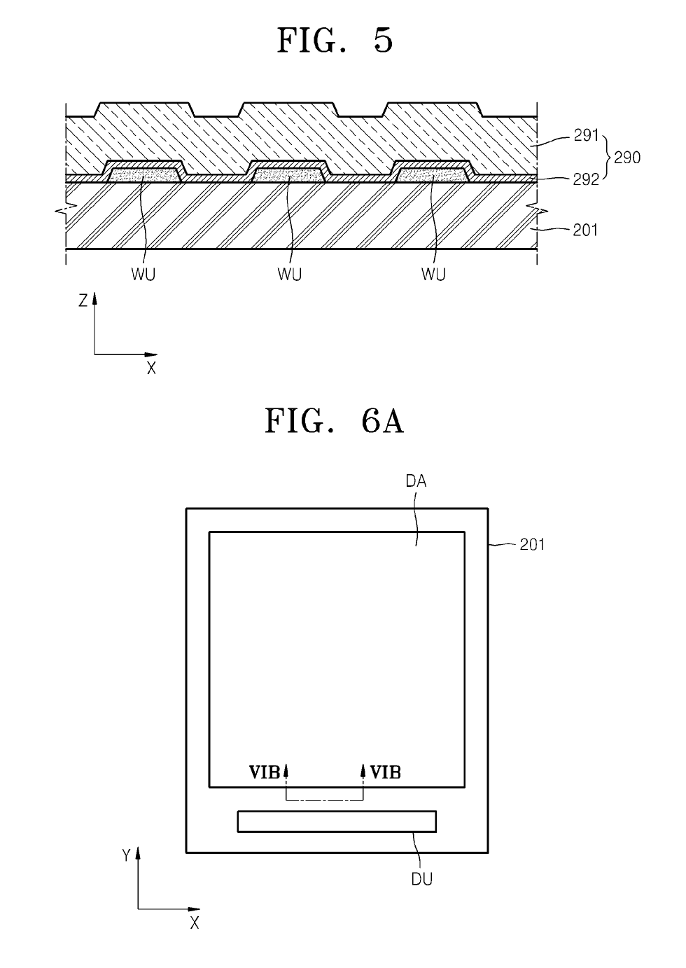

The driving unit DU is separated from the display unit DA. The driving unit DU transfers electric signals for driving the display unit DA to the display unit DA. As illustrated in FIG. 5, the wiring unit WU is interposed between the display unit DA and the driving unit DU so as to electrically connect the display unit DA to the driving unit DU.

FIG. 2 illustrates an embodiment where the display unit DA is separated from the edges of the substrate 201. However, according to other embodiments, the display unit DA extends to at least one edge of the substrate 201.

Hereinafter, each element will be described in detail.

The substrate 201 may be formed of various materials. The substrate 201 may be formed of a glass material, for example, a glass material that can transmit light therethrough. Alternatively, the substrate 201 may be formed of a flexible material, for example, a plastic material. The plastic material that forms the substrate 201 may be at least one organic material.

Alternatively, the substrate 201 may include various flexible materials, for example, a metal thin film.

The display unit DA is formed on the substrate 201 and displays images. The display unit DA may have various forms.

In the embodiment of FIGS. 2 to 5, the display unit DA includes an organic light-emitting diode (OLED) 260, but is not limited thereto. In other embodiments, the display unit DA includes a liquid crystal display or other various display technologies.

The display unit DA will be described with reference to FIGS. 3 and 4. The display unit DA includes the OLED 260, a thin film transistor (TFT) 240, and a capacitor 250.

A buffer layer 231 is formed on the substrate 201. The buffer layer 231 provides a smooth surface on an upper portion of the substrate 201. The buffer layer 231 includes an insulating material that prevents moisture and other contaminants from penetrating through the substrate 201. However, the buffer layer 231 is an optional element that can be omitted depending on the embodiment.

The TFT 240, the capacitor 250, and the OLED 260 are formed on the buffer layer 231.

The TFT 240 includes an active layer 241, a gate electrode 242, a source electrode 243, and a drain electrode 244. The OLED 260 includes a first electrode 261, a second electrode 262, and an intermediate layer 263. The capacitor 250 includes a first capacitor electrode 251 and a second capacitor electrode 252.

The active layer 241 is formed in a predetermined pattern on the buffer layer 231. The active layer 241 may include an inorganic semiconductor material such as silicon, an organic semiconductor material, or an oxide semiconductor material.

A gate insulating layer 232 is formed on the active layer 241. The gate electrode 242 is formed on the gate insulating layer 232 to correspond to the active layer 241. An interlayer insulating layer 233 is formed to cover the gate electrode 242. The source and drain electrodes 243 and 244 are formed on the interlayer insulating layer 233 to contact portions of the active layer 241. A passivation layer 234 is formed to cover the source and drain electrodes 243 and 244. Another insulating layer (not shown) may be additionally formed on the passivation layer 234 to planarize the upper surface the TFT 240.

The first capacitor electrode 251 of the capacitor 250 and the gate electrode 242 of the TFT 240 may be formed on the same layer and with the same material. Also, the second capacitor electrode 252 of the capacitor 250 and the source and drain electrodes 243 and 244 of the TFT 240 may be formed on the same layer and with the same material.

The first electrode 261 is formed on the passivation layer 234. The first electrode 261 is formed to be electrically connected to any one of the source and drain electrodes 243 and 244. Also, a pixel-defining layer (PDL) 235 is formed to cover the first electrode 261. An opening 264 is formed in the PDL 235 and the intermediate layer 263, which includes an organic emission layer, is formed in the opening 264. The second electrode 262 is formed on the intermediate layer 263.

The encapsulating unit 292, which includes the base member 291 and the barrier member 292, is formed on the second electrode 262. The encapsulating unit 290 will be described in detail below.

The display unit DA is formed in a predetermined area of the substrate 201 and the driving unit DU is separated from the display unit DA. The driving unit DU may have various forms and may include at least one integrated circuit (IC).

At least one wiring unit WU is formed on the substrate 201 to connect the display unit DA to the driving unit DU.

As illustrated in the FIG. 5 embodiment, a plurality of wiring units WU are formed on the substrate 201. Although not illustrated, at least one insulating layer may be additionally included between the substrate 201 and the wiring unit WU. That is, at least one insulating layer among the buffer layer 231, the gate insulating layer 232, the interlayer insulating layer 233, the passivation layer 234, and the PDL 235 illustrated in FIG. 4 may be interposed between the substrate 201 and the wiring unit WU. Alternatively, an insulating layer other than the buffer layer 231, the gate insulating layer 232, the interlayer insulating layer 233, the passivation layer 234, and the PDL 235 may be interposed between the substrate 201 and the wiring unit WU.

Alternatively, according to other embodiments, a conductive layer (not shown) is additionally interposed between the substrate 201 and the wiring unit WU.

The wiring unit WU electrically connects the driving unit DU to the display unit DA. Electrical signals are easily transferred between the driving unit DU and the display unit DA via the wiring unit WU. The wiring unit WU can be formed of various conductive materials. For example, the wiring unit WU may be formed by using a metal material. Alternatively, the wiring unit WU may be formed by using the same material as any one of the gate electrode 242, the source electrode 243, and the drain electrode 244.

The encapsulating unit 290 is formed to cover the wiring unit WU. The encapsulating unit 290 includes the base member 291 and the barrier member 292.

Although not illustrated, according to some embodiments, at least one protection layer (not shown) is formed between the encapsulating unit 290 and the wiring unit WU. The protection layer may include an insulating material. For example, the protection layer may include an oxide material or a nitride material. In these embodiments, the barrier member 292 of the encapsulating unit 290 contacts the protection layer.

The base member 291 is formed to include a low elastic material. Therefore, the base member 291 can be formed to have protrusions and depressions that correspond to the shape of the wiring unit WU, regardless of the thickness of the wiring unit WU formed under the base member 191. In particular, the surface of the base member 291 that faces the wiring unit WU, that is, the lower surface of the base member 291 as illustrated in FIG. 5, has a protruding and depressing surface that corresponds to the protrusions and depressions of the upper surface of the wiring unit WU. Therefore, the encapsulating unit 290 that includes the base member 291 and the barrier member 292 substantially completely encompasses the wiring unit WU to prevent moisture or external air from penetrating into the wiring unit WU.

The base member 291 includes a low elastic material that has an elasticity of about 10 Mpa or less. Therefore, the upper surface of the base member 291 is formed to not have a smooth surface but to have a protruding and depressing surface that corresponds to the shape of the wiring unit WU.

According to one embodiment, the base member 291 includes a thermoplastic resin. For example, the base member 291 includes MMA, PC, PET, COP, COC, polyimide, or a combination thereof. Respective glass transition temperatures (Tg) of the above-described materials are about 80° C. to about 100° C. or greater. During a process of forming the encapsulating unit 290 including the base member 291, the working temperature is greater than the Tg of the above-described materials.

According to another embodiment, the base member 291 includes an elastomer. For example, the base member 291 includes styrene-based synthetic rubber or silicon-based synthetic rubber. Also, the base member 291 may include a block copolymer of MMA and BA.

According to yet another embodiment, the base member 291 is a hot melt adhesive, including a polyester-based hot melt film, a synthetic rubber-based hot melt film, a modified olefin based hot melt film, an EVA based hot melt film, an isocyanate-based hot melt film, or a combination thereof.

According to still yet another embodiment, the base member 291 is an adhesive film having a low elasticity, including an acryl-based adhesive film, a synthetic rubber-based adhesive film, a polyester-based adhesive film, a silicon rubber-based adhesive film, a urethane-based adhesive film, or a combination thereof.

The barrier member 292 is formed on the wiring unit WU to cover the wiring unit WU. Also, the barrier member 292 contacts the base member 291. In some embodiments, the barrier member 292 includes an inorganic material, such as an oxide material or a nitride material. In other embodiments, the barrier member 292 includes at least one inorganic layer and at least one organic layer. In these embodiments, the surface of the barrier member 292 that is closest to the wiring unit WU is an inorganic layer.

The barrier member 292 has a predetermined thickness. The thickness of the barrier member 292 is less than the thickness of the base member 291. Specifically, in some embodiments, the thickness of the barrier member 292 is about 1 μm or less. Therefore, the barrier member 292 has a protruding and depressing surface corresponding to the shape of the wiring unit WU and cracks are not formed in the barrier member 292 when the protrusions and depressions are formed. However, according to other embodiments, the thickness of the barrier member 292 is greater than about 1 μm.

In some embodiments, the thickness of the barrier member 292 is about 0.01 μm or greater. When the thickness of the barrier member 292 is less than about 0.01 μm, an encapsulating properties thereof decrease. However, according to other embodiments, the thickness of the barrier member 292 is less than about 0.01 μm.

The base member 291 has predetermined thicknesses. Specifically, the portion of the base member 291 that corresponds to the wiring unit WU has a predetermined thickness and the portion of the base member 291 that does not correspond to the wiring unit WU has a predetermined thickness. The two thicknesses are the same as or similar to each other. Since the base member 291 includes a low elastic material and thus has protrusions and depressions that correspond to the protrusions and depressions of the wiring unit WU, the base member 291 has a substantially uniform thickness throughout.

The base member 291 is thicker than the barrier member 292 and has a thickness of about 5 μm to about 100 μm. When the thickness is less than about 5 μm, the encapsulating properties thereof decrease, thereby decreasing the ability of the base member 291 to block moisture and external air transmission. When the thickness is greater than about 100 μm, the base member 291 may not be able to easily form protrusions and depressions that correspond to the wiring unit WU, and thus the contact strength between the encapsulating unit 190 and the wiring unit WU may decrease. However, depending on the embodiment, the base member 291 can have a thickness that is less than about 5 μm or greater than about 100 μm.

The display device 200 according to the embodiment of FIGS. 205 includes the encapsulating unit 290 that covers the wiring unit WU. The encapsulating unit 290 includes the base member 291 and the barrier member 292. Regardless of the thickness or width of the wiring unit WU, the encapsulating unit 290 is easily formed to attach to the upper surface of the wiring unit WU by forming the base member 291 by using the above-described materials, in particular, a low elastic material having an elasticity of about 10 MPa or less.

The thickness of the barrier member 292 that is formed near the wiring unit WU is formed to be less than the thickness of the base member 291, for example, about 1 μm or less. Therefore, the barrier member 292 is formed to have protrusions and depressions that correspond to the shape of the wiring unit WU so that the barrier member 292 and the wiring unit WU are not separated and contact each other.

In other embodiments, when the at least one insulating layer is interposed between the wiring unit WU and the barrier member 292, the barrier member 292 contacts the insulating layer.

Accordingly, the encapsulating properties of the display device 200 are improved, and thus the durability thereof is improved. Since the encapsulating unit 290 is flexible overall, when the substrate 101 is formed of a flexible material, it is possible to easily form a display device 200 that can be bent or folded by a user.

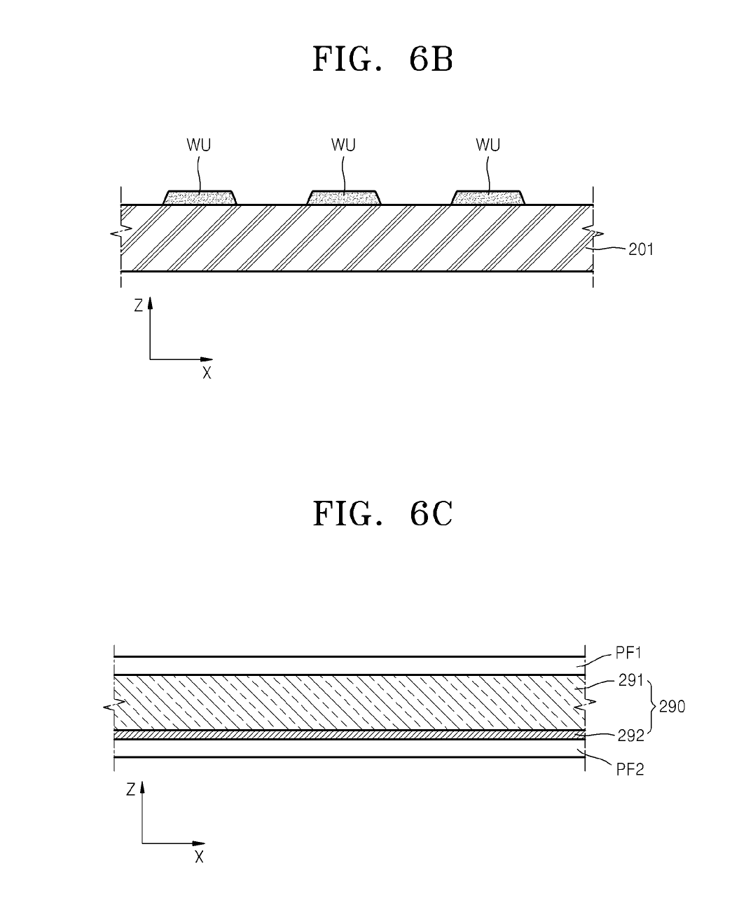

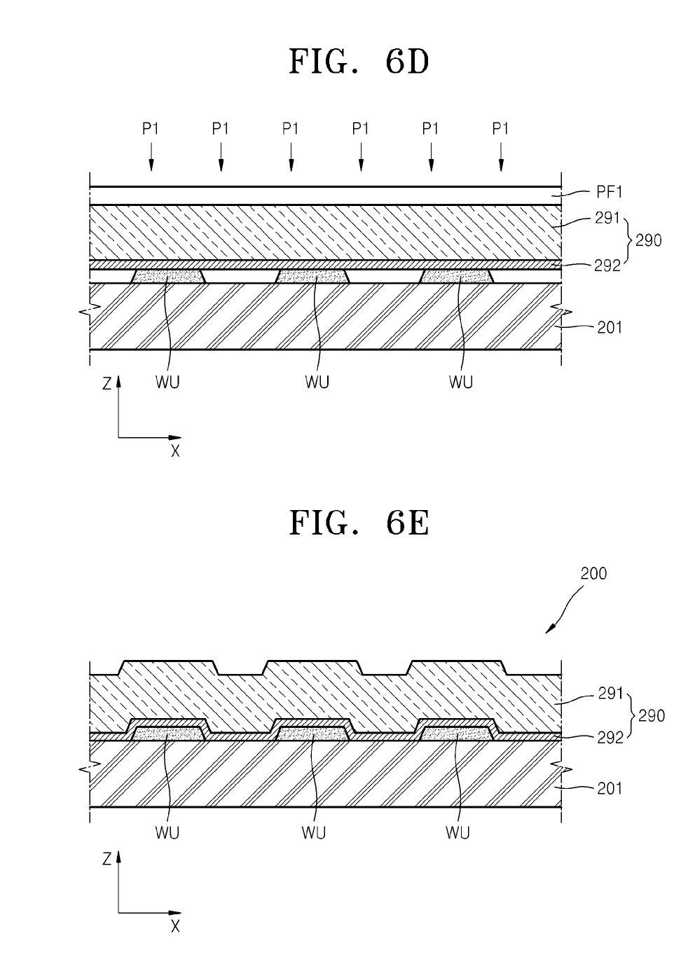

FIGS. 6A to 6E are views sequentially illustrating a method of manufacturing a display device according to an embodiment. Specifically, FIGS. 6A to 6E are views that sequentially illustrate a method of manufacturing the display device 200 of FIG. 2, but are not limited thereto. However, the method of FIGS. 6A to 6E can be applied to the display device 100 of FIG. 1 and other various display devices.

Referring to FIGS. 6A and 6B, the display unit DA, the driving unit DU, and the wiring unit WU are formed on the substrate 201. FIG. 6B is a cross-sectional view taken along line VIB-VIB of the display device of FIG. 6A.

The display unit DA of the display device 200 displays images that can be recognized at least by a user. The display unit DA can be embodied in various forms and may include, for example, an OLED, as in the above-described embodiments.

The driving unit DU is separated from the display unit DA. The driving unit DU transfers the electric signals for driving the display unit DA to the display unit DA. The wiring unit WU is interposed between the display unit DA and the driving unit DU so as to electrically connect the display unit DA to the driving unit DU.

In some embodiments, the wiring unit WU is simultaneously formed with a conductive layer such as an electrode (not shown) of the display unit DA.

Referring to FIG. 6C, the encapsulating unit 290 is prepared. The encapsulating unit 290 includes the base member 291 and the barrier member 292. In order to protect both surfaces of the encapsulating unit 290, a first protection film PF1 and a second protection film PF2 are respectively attached to an upper surface of the base member 291 and a lower surface of the barrier member 292. However, the described technology is not limited thereto, and the first and second protection films PF1 and PF2 may be omitted.

The process of preparing the encapsulating unit 290 illustrated in FIG. 6C can be performed independently from the process of forming the display unit DA, the driving unit DU, and the wiring unit WU on the substrate 201 illustrated in FIGS. 6A and 6B, regardless of a predetermined order.

Referring to FIG. 6D, the encapsulating unit 290 is arranged such that the encapsulating unit 290 is substantially aligned with the substrate 201. That is, the encapsulating unit 290 is placed to face at least the display unit DA and the wiring unit WU formed on the substrate 201. Specifically, the barrier member 292 of the encapsulating unit 290 is arranged closer to the substrate 201 than the base member 291.

Here, the second protection film PF2 is removed. Then, pressure P1 is applied to the upper portion of the encapsulating unit 290. Although FIG. 6D illustrates an embodiment where the pressure P1 is applied while the first protection film PF1 is still attached to the encapsulating unit 290, the described technology is not limited thereto. That is, the first protection film PF1 may be removed before the pressure P1 is applied. Thereafter, the encapsulating unit 290 has a shape effectively corresponding to the protrusions and depressions of the wiring unit WU and thus is formed to easily contact the wiring unit WU.

In order to easily apply the pressure P1, the pressure P1 can be applied to the barrier member 292 of the encapsulating unit 290 while the barrier member 292 contacts the wiring unit WU.

Although not illustrated, a stage that supports any one of the substrate 201 and the encapsulating unit 290 can be employed and then the pressure P1 can be applied via the stage. The pressure P1 is applied at a temperature equal to or greater than a predetermined temperature. That is, the pressure P1 is applied at a glass transition temperature (Tg) of the base member 291 of the encapsulating unit 290 or at a greater temperature. By performing the pressing and heating processes, the encapsulating unit 290 is formed to be attached to the wiring unit WU having a small line width and height and the encapsulating unit 290 has a protruding and depressing surface that corresponds to the shape of the wiring unit WU.

Although not illustrated, a separate process can be performed before the applying the pressure P1 to attach the encapsulating unit 290 to the wiring unit WU. The separate process increases the adhesion between the encapsulating unit 290 and an area of the substrate 201 that does not correspond to the wiring unit WU, i.e., an area of the substrate 201 in which the wiring unit WU and the driving unit DU are not formed, such as a left side, a right side, and an upper side of the display unit DA.

For example, before applying the pressure P1, laser may be locally irradiated so that the encapsulating unit 290 contacts and is attached to the substrate 201.

Although not illustrated, in other embodiments, at least one protection layer is formed between the encapsulating unit 290 and the wiring unit WU. The protection layer may include an insulating material. For example, the protection layer may include an oxide material or a nitride material.

By applying the pressure P1, the display device 200, in which the encapsulating unit 290 is formed to cover the wiring unit WU and the display unit DA, is manufactured as illustrated in FIG. 6E. The encapsulating unit 290 is formed to be attached to the wiring unit WU having a small width.

In some embodiments, a preliminary process is performed before applying the pressure P1 so as to increase the contact strength and adhesion strength between the encapsulating unit 290 and the substrate 201. In particular, the preliminary process can be performed to increase the contact strength and adhesion strength between the wiring unit WU and the encapsulating unit 290 and between an area of the substrate 201 near the wiring unit WU and the encapsulating unit 290.

That is, before applying the pressure P1, a surface treatment process can be performed on the wiring unit WU, the area of the substrate 201 near the wiring unit WU, and the encapsulating unit 290.

According to an embodiment, the surface treatment process includes performing surface activated bonding. A silicon thin film is formed, e.g, a film having a thickness of about 10 nm, on an area where the encapsulating unit 290 and the substrate 201 contact each other, e.g., a surface of the barrier member 292 of the encapsulating unit 290 and an upper surface of the substrate 201 or a surface of the wiring unit WU corresponding to the surface of the barrier member 292. Next, energy, for example, in the form of an ion beam, is irradiated to activate the silicon layers that face each other and the pressure P1 is applied as described above. Accordingly, the contact strength and the adhesion strength between the substrate 201 and the encapsulating unit 290 are increased. Also, the display device 200 may block more moisture and external air from penetrating therein due to the addition of the silicon layers, and thus the durability thereof can be improved.

According to another embodiment of the surface treatment process, a plasma process is performed before applying the pressure P1. The surface of the encapsulating unit 290, i.e., a surface of the barrier member 292, and the upper surface of the substrate 201 or the surface of the wiring unit WU corresponding to the surface of the barrier member 292, is plasma-processed. In order to prevent damage to components of the display device 200 due to the plasma, it is possible to plasma process only the surface of the barrier member 292 of the encapsulating unit 290.

When the pressure P1 is applied after the plasma process, impurities in areas of the substrate 201 and the encapsulating unit 290 that contact each other can be removed, thereby forming a smooth surface. Accordingly, the contact strength and the adhesion strength between the substrate 201 and the encapsulating unit 290 are increased. Also, the display device 200 can block more moisture and external air from penetrating therethrough, and thus the durability thereof can be improved.

According to another embodiment of the surface treatment process, a monomolecular layer is formed before applying the pressure P1. The monomolecular layer is formed on the surface of the encapsulating unit 290 and the upper surface of the substrate 201 or the surface of the wiring unit WU corresponding to the upper surface of the encapsulating unit 290. For example, when the pressure P1 is applied after a self-assembled monolayer (SAM) is formed, the contact strength and the adhesion strength between the substrate 201 and the encapsulating unit 290 are increased. Also, the display device 200 can block more moisture and external air from penetrating therethrough, and thus the durability thereof can be improved.

According to another embodiment of the surface treatment process, a molecular film having a triazine-based functional group is formed before applying the pressure P1. The molecular film having a triazine-based functional group is formed on the surface of the encapsulating unit 290, and the upper surface of the substrate 201 or the surface of the wiring unit WU corresponding to the upper surface of the encapsulating unit 290.

According to another embodiment of the surface treatment process, a silane coupling agent is formed before applying the pressure P1. The silane coupling agent is formed on the surface of the encapsulating unit 290, the upper surface of the substrate 201 corresponding to the upper surface of the encapsulating unit 290, or the surface of the wiring unit WU.

The method of manufacturing the display device 200, according to the embodiment of FIGS. 6A to 6E, includes forming the encapsulating unit 290 to cover the wiring unit WU. The encapsulating unit 290 includes the base member 291 and the barrier member 292. Regardless of the thickness or the width of the wiring unit WU, the encapsulating unit 290 is formed to contact the upper surface of the wiring unit WU by forming the base member 291 of a low elastic material having an elasticity of about 10 MPa or less. That is, the base member 291 is formed to have a protruding and depressing upper surface that corresponds to the shape of the wiring unit WU.

The barrier member 292 that is formed near the wiring unit WU is formed to have a thickness that is less than the thickness of the base member 291, specifically, a thickness of about 1 μm or less. Therefore, the barrier member 292 is formed to have protrusions and depressions that correspond to the shape of the wiring unit WU so that the barrier member 292 and the wiring unit WU are not separated and contact each other. According to other embodiments, the base member is formed to have a thickness of greater than about 1 μm.

Alternatively, according to other embodiments, when the at least one insulating layer is interposed between the wiring unit WU and the barrier member 292, the barrier member 292 contacts the insulating layer.

Accordingly, the encapsulating properties of the display device 200 are improved, and thus the durability thereof is improved. Since the encapsulating unit 290 is flexible overall, when the substrate 201 is formed of a flexible material, it is possible to easily form a display device 200 that can be bent or folded by a user

As described above, according to at least one embodiment, a display device and a method of manufacturing the same improves the encapsulating properties and durability of the display device.

It should be understood that the exemplary embodiments described herein should be considered in a descriptive sense only and not for purposes of limitation. Descriptions of features or aspects within each embodiment should typically be considered as available for other similar features or aspects in other embodiments.

While one or more embodiments of the inventive technology have been described with reference to the figures, it will be understood by those of ordinary skill in the art that various changes in form and details may be made therein without departing from the spirit and scope of the invention as defined by the following claims.

What is claimed is:

1. A display device, comprising:
a substrate;
at least one wire formed over the substrate and configured to transfer a signal for displaying an image; and
an encapsulating unit formed over the wire and comprising a base layer and a barrier layer,
wherein the barrier layer is interposed between the wire and the base layer and comprises i) a lower surface having a shape that corresponds to the shape of the wire and ii) an upper surface opposing the lower surface,
wherein the base layer has a lower surface having a shape that corresponds to the shape of the barrier layer.

2. The display device of claim 1, wherein the base layer has an elasticity of about 10 MPa or less.

3. The display device of claim 1, wherein the base layer is formed of thermoplastic resin, elastomer, a hot melt adhesive, or a low elastic adhesive film.

4. The display device of claim 1, wherein the barrier layer is formed of an inorganic material.

5. The display device of claim 1, wherein the barrier comprises at least one inorganic layer and at least one organic layer that are stacked and wherein the at least one inorganic layer is formed on the lower surface of the barrier layer.

6. The display device of claim 1, wherein the barrier layer contacts the wire.

7. The display device of claim 1, wherein the base layer has a upper surface having a shape that corresponds to the shape of the the wire.

8. The display device of claim 1, wherein the base layer is thicker than the barrier layer.

9. The display device of claim 1, wherein the thickness of the barrier layer is in the range of about 0.01 μm to about 1 μm.

10. The display device of claim 1, further comprising:
a display unit formed on the substrate and configured to display the image; and
a driver separated from the display unit and configured to drive the display unit,
wherein the wire electrically connects the display unit to the driver.

11. The display device of claim 10, wherein the display unit comprises an organic light-emitting diode (OLED) and wherein the OLED comprises a first electrode, a second electrode, and an intermediate layer i) interposed between the first and second electrodes and ii) comprising an organic emission layer.

12. A method of manufacturing a display device, comprising:
providing a substrate;
forming at least one wire over the substrate; and forming an encapsulating unit over the wire, wherein the encapsulating unit comprises a base layer and a barrier layer,
wherein the barrier layer is interposed between the wire and the base layer and comprises i) a lower surface having a shape that corresponds to the shape of the wire and ii) an upper surface opposing the lower surface, and
wherein the base layer has a lower surface having a shape that corresponds to the shape of the barrier layer.

13. The method of claim 12, wherein the forming of the encapsulating unit comprises applying pressure to at least one of the encapsulating unit and the substrate.

14. The method of claim 13, wherein the pressure is applied at a temperature that is substantially equal to or greater than a glass transition temperature of the base layer.

15. The method of claim 13 further comprising, before applying the pressure, forming a silicon thin film on a surface of the barrier layer of the encapsulating unit and a surface of the substrate and a surface of the wire, which are at a location corresponding to the surface of the barrier layer, and then irradiating energy to activate the silicon thin film.

16. The method of claim 13, further comprising performing a plasma process on each of i) the lower surface of the barrier layer and ii) at least one of an upper surface of the substrate and an upper surface of the wire before the applying the pressure.

17. The method of claim 13, further comprising forming a monomolecular layer on each of i) the lower surface of the barrier layer and ii) at least one of an upper surface of the substrate and an upper surface of the wire before the applying the pressure.

18. The method of claim 12, wherein the barrier layer is formed of an inorganic material.

19. The method of claim 12, wherein the base is thicker than the barrier layer.

20. A display device, comprising:
a substrate;
at least one wire formed over the substrate and configured to transfer a signal for display an image;
a first encapsulation layer formed over the wire and including i) a lower surface having a shape that corresponds to the shape of the wire and ii) an upper surface opposing the lower surface; and
a second encapsulation layer formed over the first encapsulation layer and including a lower surface having a shape that corresponds to the shape of the first encapsulation layer.
